(19) United States
(12) Patent Application Publication
(10) Pub. No.: US 2009/0097307 A1
(43) Pub. Date: Apr. 16, 2009

(54) Phase-change random access memory device, system having the same, and associated methods

(76) Inventors: Joon-min Park, Seoul (KR); Young-kug Moon, Suwon-si (KR); Sang-ki Hwang, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/285,657

(22) Filed: Oct. 10, 2008

(30) Foreign Application Priority Data
Oct. 12, 2007 (KR) 10-2007-0103172

(51) Int. Cl. G11C 11/00; G11C 8/00; G11C 7/06

(52) U.S. Cl. 365/163; 365/148; 365/230.03; 365/205

(57) ABSTRACT

A phase-change random access memory (PRAM) device includes a PRAM cell array having a first bank that includes first to m^{th} sectors, where m is a positive integer of at least 2, and sense amplifiers disposed between an x^{th} sector and an (x+1)^{th} sector of the bank, where x is a positive integer less than m.

### BACKGROUND

1. Technical Field

Embodiments relate to a phase-change random access memory device, a system having the same, and associated methods.

2. Description of the Related Art

FIG. 1 illustrates an equivalent circuit diagram of a unit cell of a phase-change random access memory (PRAM) device that includes a phase-change material GST. Referring to FIG. 1, the unit cell C may include a memory device ME and a P-N diode D. A bit line BL may be connected to the phase-change material GST, which may be connected to a P-junction of the diode D. A word line WL may be connected to an N-junction of the diode D. In another circuit (not shown), the PRAM device may include a transistor connected to the phase-change material GST instead of the diode D.

In the PRAM device, current supplied to the bit line BL to perform write and read operations may influence subsequent write and read operations. For example, when an operation of writing data “1” in a first cell connected to a first bit line is performed, a current is supplied to the first bit line. An undesirable voltage may sometimes be present in the first bit line even when the operation of writing data “1” is terminated. Due to this undesirable voltage, a subsequent write operation of the first cell may be inaccurately performed, or the write or read operations of the first cell may be erroneously performed during the write and read operations of another cell.

The PRAM device writes and reads data corresponding to the state of the phase-change material. Thus, it is important to accurately sense the state of the phase-change material. As the capacity of the PRAM device increases, accurately and quickly sensing the state of the phase-change material is becoming more important. In addition, reductions in layout area of the PRAM device are desired.

### SUMMARY

Embodiments are therefore directed to a phase-change random access memory device, a system having the same, and associated methods, which substantially overcome one or more of the problems due to the limitations and disadvantages of the related art.

It is therefore a feature of an embodiment to provide a phase-change random access memory device having sense amplifiers disposed between sectors of a memory cell array bank.

It is therefore another feature of an embodiment to provide a phase-change random access memory device having sense amplifiers coupled to at least two banks of a memory cell array.

At least one of the above and other features and advantages may be realized by providing a phase-change random access memory (PRAM) device, including a PRAM cell array having a first bank that includes first to m^{th} sectors, where m is a positive integer of at least 2, and sense amplifiers disposed between an x^{th} sector and an (x+1)^{th} sector of the bank, where x is a positive integer less than m.

The PRAM device may further include a first group of global bit lines connected to the first through x^{th} sectors, and a second group of global bit lines connected to the (x+1)^{th} through m^{th} sectors. A plurality of global bit lines from the first group of global bit lines and a plurality of global bit lines from the second group of global bit lines may each be connected to a same sense amplifier disposed between the x^{th} sector and the (x+1)^{th} sector. Exactly one global bit line from the first group of global bit lines and exactly one global bit line from the second group of global bit lines may be connected to a same sense amplifier disposed between the x^{th} sector and the (x+1)^{th} sector.

The PRAM device may further include global bit line selection units configured to connect the sense amplifiers to corresponding global bit lines. The global bit line selection units may each include a transistor, a gate of the transistor may be controlled by a global bit line selection signal, and the transistor may be configured to couple a sense amplifier to a corresponding global bit line.

The global bit line selection units may be disposed between adjacent sectors. Global bit line selection units coupled to the first through x^{th} sectors may be disposed between the x^{th} sector and the (x+1)^{th} sector, and global bit lines selection units coupled to the (x+1)^{th} through m^{th} sectors may be disposed between the x^{th} sector and the (x+1)^{th} sector.

The PRAM device may further include a plurality of global bit lines, each of the global bit lines connected to each of the first to the m^{th} sectors. Each of the sense amplifiers may be connected to at least two bit lines of the plurality of global bit lines. The PRAM device may further include global bit line selection units configured to couple one of the at least two bit lines to a single sense amplifier. Each of the at least two bit lines may be connected to a respective bit line selection unit disposed between the bit line and the sense amplifier. Each of the sense amplifiers may be connected to exactly one global bit line of the plurality of global bit lines. The x^{th} sector may be an m/2^{th} sector when m is a multiple of 2, and the x^{th} sector may be a (m±1)/2^{th} sector when m is not a multiple of 2.

At least one of the above and other features and advantages may also be realized by providing a phase-change random access memory (PRAM) device, including a PRAM cell array having a plurality of banks, and a plurality of sense amplifiers, each sense amplifier being connected to at least two banks of the plurality of banks.

A first group of global bit lines may be connected to a first bank of the plurality of banks, and a second group of global bit lines may be connected to a second bank of the plurality of banks. A plurality of global bit lines from the first group of global bit lines and a plurality of global bit lines from the second group of global bit lines may each be connected to a same sense amplifier. Exactly one global bit line from the first group of global bit lines and exactly one global bit line from the second group of global bit lines may be connected to a same sense amplifier.

At least one of the above and other features and advantages may also be realized by providing a phase-change random access memory (PRAM) system, including a PRAM cell array having a first bank that includes first to m^{th} sectors, where m is a positive integer of at least 2, and a memory controller configured to control operations of the memory cell array. Sense amplifiers may be disposed between an x^{th} sector and an (x+1)^{th} sector of the bank, where x is a positive integer less than m.

At least one of the above and other features and advantages may also be realized by providing a method of operating a memory system having a phase-change random access memory (PRAM) cell array, the method including controlling set and reset states of cells in a bank of the PRAM cell array, the bank having first and second sectors, and sensing the set and reset states of the cells using sense amplifiers disposed between an x^{th} sector and an (x+1)^{th} sector of the bank, where x is a positive integer less than m.

### BRIEF DESCRIPTION OF THE DRAWINGS

The above and other features and advantages will become more apparent to those of ordinary skill in the art by describing in detail example embodiments with reference to the attached drawings, in which:

FIG. 1 illustrates an equivalent circuit diagram of a unit cell of a PRAM device;

FIG. 2 illustrates a cross-sectional view of a memory device including a phase-change material;

FIG. 3 illustrates a graph of characteristics of the phase-change material of FIG. 2;

FIG. 4 illustrates a schematic block diagram of a PRAM device according to a first embodiment;

FIG. 5 illustrates a circuit diagram of a bank of FIG. 4;

FIG. 6 illustrates a circuit diagram of a PRAM device according to a second embodiment;

FIG. 7 illustrates a circuit diagram of a PRAM device according to a third embodiment;

FIG. 8 illustrates a circuit diagram of a PRAM device according to a fourth embodiment;

FIG. 9 illustrates a circuit diagram of a PRAM device according to a fifth embodiment; and

FIG. 10 illustrates a schematic block diagram of a memory system according to embodiments.

### DETAILED DESCRIPTION

Korean Patent Application No. 10-2007-0103172, filed on Oct. 12, 2007, in the Korean Intellectual Property Office, and entitled: “Phase-Change Random Access Memory Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

PRAMs may be used to form non-volatile memories that store data using materials, such as Ge—Sb—Te (GST) (phase-change materials), whose resistances change upon phase transition brought about by a change in temperature. PRAMs may provide non-volatile properties and low power consumption properties, in addition to the advantages of DRAMs.

The phase-change material (Ge—Sb—Te) of a PRAM cell may transform into a crystalline state or an amorphous state, depending on the temperature and duration of heating applied to the phase-change material, thereby storing data in the PRAM cell. In general, a high temperature above 900° C. is required for a phase transition of the phase-change material. Such high temperatures may be obtained by Joule heating caused by current flowing through the PRAM cell.

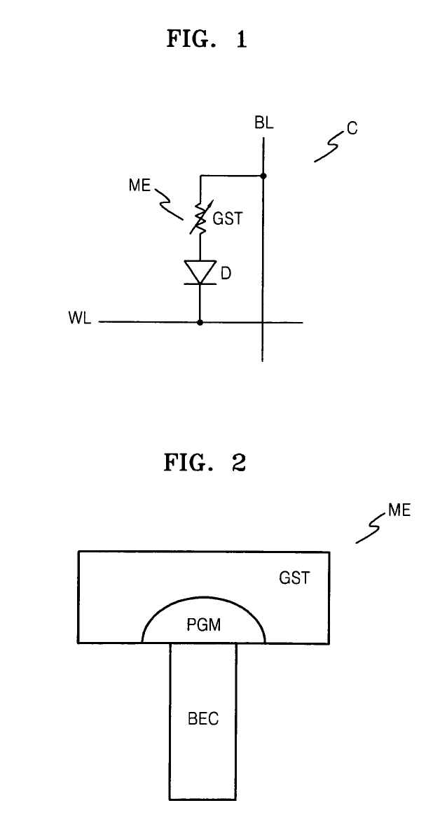

FIG. 2 illustrates a cross-sectional view of a phase-change material in a PRAM device. Referring to FIG. 2, PMG represents a contact region between the phase-change material GST and the bottom electrode BEC. If a current is supplied to a bottom electrode contact BEC of the memory device ME, the volume and state of PGM are changed, and the change of PGM determines the crystalline state of the phase-change material GST.

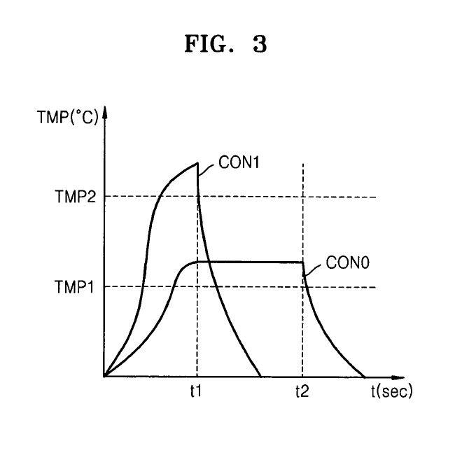

FIG. 3 illustrates a graph of characteristics of the phase-change material of FIG. 2. Referring to FIG. 3, “CON 1” indicates conditions for changing the phase-change material to an amorphous state, and “CON0” indicates conditions for changing the phase-change material to a crystalline state.

A write operation and a read operation of the PRAM device will be described with reference to FIG. 3. First, a write operation will be described. In order to store data “1”, the phase-change material is heated to a temperature above its melting temperature TMP2 (time t1), and then rapidly cooled. Then, the phase-change material GST goes into an amorphous state. Such an amorphous state may be defined as data “1”, and may be referred to as a reset state.

In order to store data “0”, the phase-change material is heated to a temperature above its crystalline temperature TMP1 for a predetermined period of time (time t2), and gradually cooled. Then, the phase-change material goes into a crystalline state. Such a crystalline state may be defined as data “0”, and may be referred to as a set state.

Next, a read operation will be described. A bit line and a word line are selected in order to select a memory cell to be read. A read current may be supplied to the selected memory cell to determine whether data stored in the selected memory cell is “1” or “0” based on a voltage change caused by a resistance of the phase-change material GST of the selected memory cell. Thus, the PRAM device may write and read data corresponding to the state of the phase-change material.

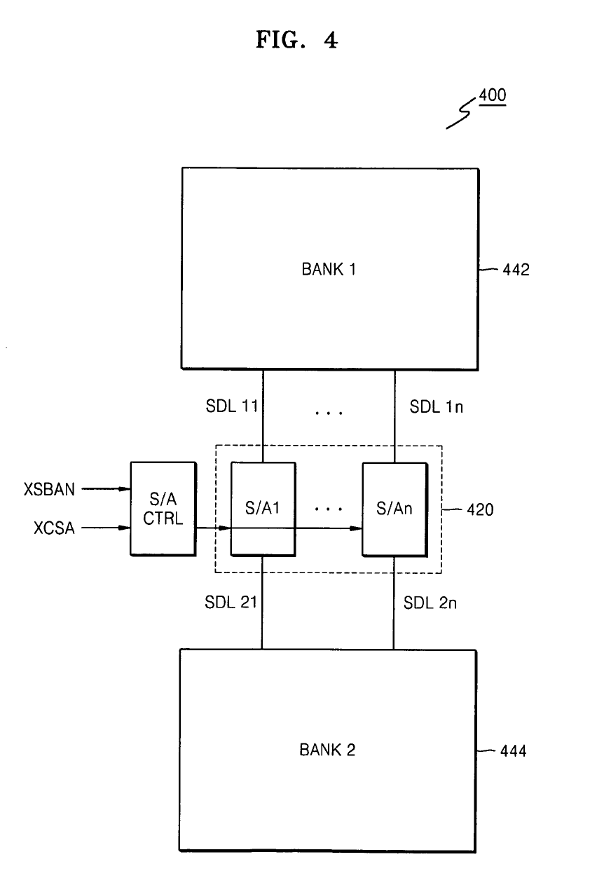

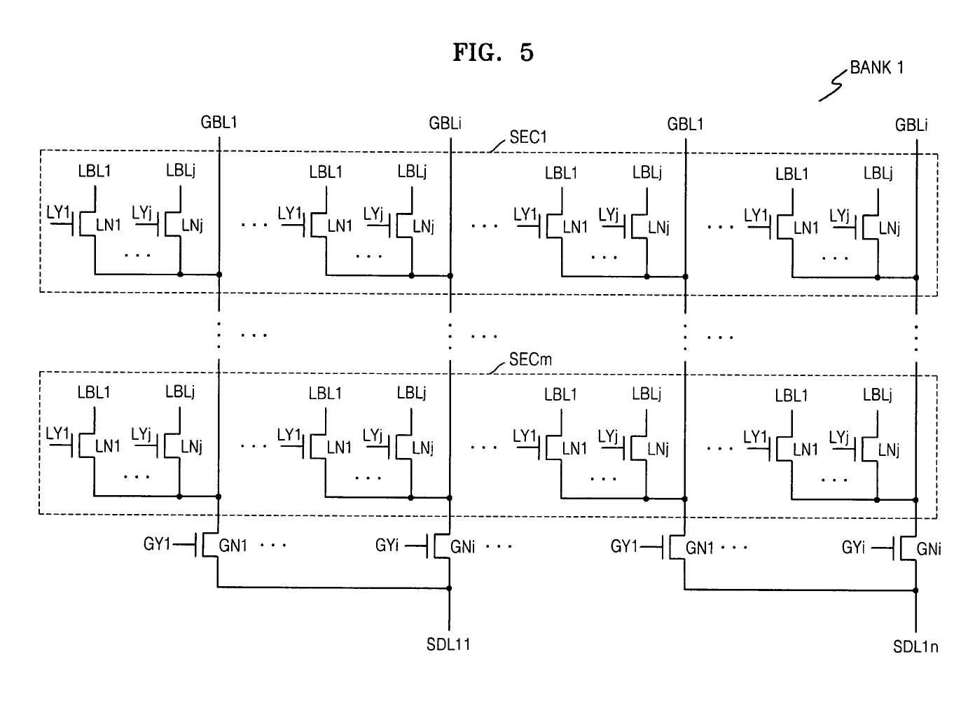

FIG. 4 illustrates a schematic block diagram of a PRAM device 400 according to a first embodiment, and FIG. 5 illustrates a circuit diagram of a bank of FIG. 4.

Referring to FIG. 4, the PRAM device 400 may include memory cell array including a first bank 442 (BANK1) and a second bank 444 (BANK2), and a plurality of sense amplifiers (S/A) 420. In the PRAM device of FIG. 4, a sense amplifier S/A may be shared by a plurality of banks, and thus a layout area of the PRAM device may be reduced.

The PRAM device 400 may further include a sense amplifier controlling unit S/A CTRL. The sense amplifier controlling unit S/A CTRL may control, e.g., by responding to a bank selection signal XSBAN and a control signal XCSA, each of the sense amplifiers S/A1 to S/An to perform a sensing operation for corresponding bit lines of the bank. For example, the bank selection signal XSBAN may control selection of the first bank 442 and the control signal XCSA may control activation of the first sense amplifier S/A1. Accordingly, the sense amplifier controlling unit S/A CTRL may activate the first sense amplifier S/A1 and the first sense amplifier S/A1 may perform a sensing operation for SDL 11.

FIG. 5 illustrates the first bank 442 (BANK1) of FIG. 4. The second bank 444 may have the same structure. Referring to FIG. 5, the first bank 442 may include a plurality of sectors SEC1 to SECm, global bit lines GBL1 to GBLi and local bit lines LBL1 to LBLj. Each of the global bit lines GBL1 to GBLi may be connected to a plurality of local bit lines LBL1 to LBLj. Each of the local bit lines LBL1 to LBLj may be connected to PRAM cells.

Each of the global bit lines GBL1 to GBLi may be connected to a corresponding global bit line selection transistor GN1 to GNi. Each of the local bit lines LBL1 to LBLj may be connected to a corresponding local bit line selection transistor LN1 to LNj. A cell to be written or read may be selected by turning-on a global bit line transistor and a local bit line transistor corresponding to the cell. A voltage may be applied to a word line (not shown) corresponding to the cell.

Referring to FIG. 5, each of the sense amplifier data lines SDL 11 to SDL1n may be connected to multiple ones of the plurality of global bit lines GBL1 to GBLi, i.e., in a one-to-many configuration. Thus, a single sense amplifier S/A may sense a plurality of global bit lines that are connected to the corresponding sense amplifier data line. In another implementation, a single sense amplifier may sense a single global bit line, and a separate sense amplifier data line may not be implemented.

The sense amplifiers S/A1 to S/An may be shared by multiple banks among the plurality of banks. For example, as shown in FIG. 4, sense amplifiers S/A1 to S/An may be shared by two banks, i.e., first bank 442 and second bank 444.

Referring to FIGS. 4 and 5, each of sense amplifier data lines SDL11 to SDL1n and SDL21 to SDL2n may be connected to a sense amplifier data line SDL of a corresponding sense amplifier S/A, and each sense amplifier data line SDL may be connected to a plurality of global bit lines. Thus, each of the sense amplifiers S/A1 to S/An may be shared by a plurality of global bit lines drawn from among the global bit lines of the first bank 442 and the global bit lines of the second bank 444. For example, the first sense amplifier S/A1 may be shared by a plurality of global bit lines of the first bank 442 that are connected to the sense amplifier data line SDL11. Further, the first sense amplifier S/A1 may also be shared by a plurality of global bit lines of the second bank 444 that are connected to the sense amplifier data line SDL21.

In another implementation, each of the sense amplifier data lines SDL11 to SDL1n and SDL21 to SDL2n may be connected to one corresponding global bit line, such that each of the sense amplifiers S/A1 to S/An is shared by one global bit line of the first bank 442 and one global bit line of the second bank 444. For example, the first sense amplifier S/A1 may be shared by the global bit line connected to sense amplifier data line SDL11 of the first bank 442 and the global bit line connected to sense amplifier data line SDL21 of the second bank 444. Thus, the first sense amplifier S/A1 may perform a sensing operation for the global bit line connected to SDL11 and the global bit line connected to SDL21.

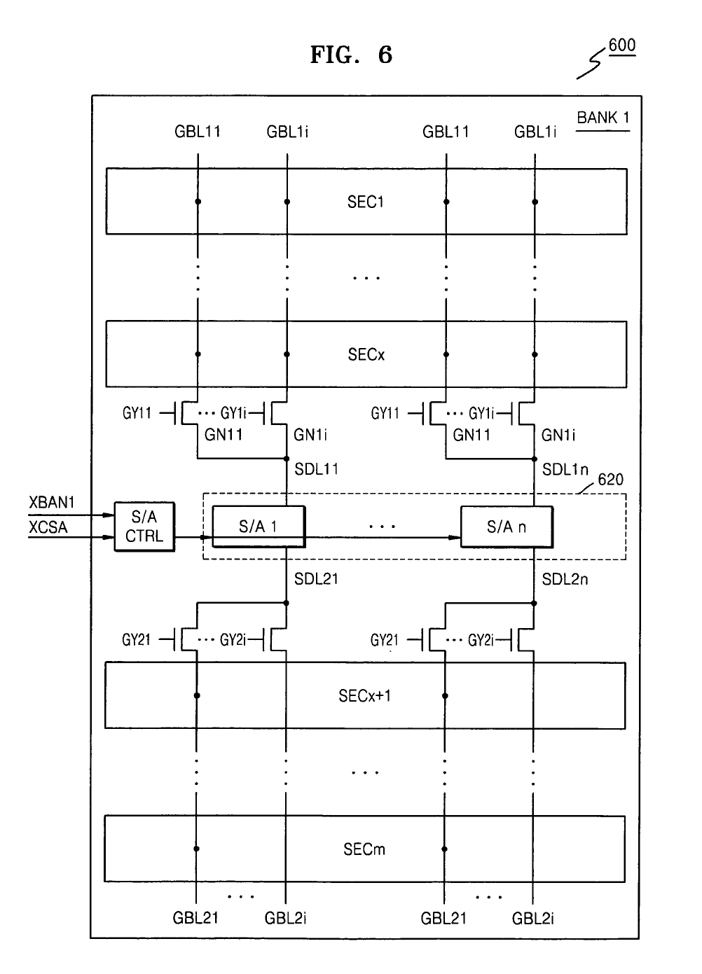

FIG. 6 illustrates a circuit diagram of a PRAM device 600 according to a second embodiment.

Referring to FIG. 6, the PRAM device 600 may include a bank BANK1 and a plurality of sense amplifiers 620 (S/A1 to S/An). The PRAM device 600 of FIG. 6, like the PRAM device 400 of FIG. 4, may include a plurality of banks.

The bank BANK1 may include a first sector to an m^{th} sector SEC1 to SECm, where m is a positive integer. The bank BANK1 of FIG. 6, like the bank BANK1 of FIG. 5, may have a structure in which a single sense amplifier data line, e.g., each of SDL11 . . . SDL1n and SDL21 . . . SDL2n, is connected to a plurality of global bit lines from among the global bit lines GBL11 to GBL1i and GBL21 to GBL2i.

Referring to FIG. 6, the sense amplifiers S/A1 to S/An may be disposed between a x^{th} sector SECx and a (x+1)^{th} sector SECx+1, where x is a positive integer less than m. Thus, the sense amplifiers S/A1 to S/An of the PRAM device 600 may not be disposed at the top or bottom of the bank, but rather disposed between multiple sectors, e.g., arbitrary sectors. In an implementation, as shown in FIG. 6, the sense amplifiers S/A1 to S/An may be positioned in consideration of sensing operations and may be disposed at the center of the bank.

The bank BANK1 may be divided into two parts by the sense amplifiers S/A1 to S/An, e.g., the bank BANK1 may be divided into two parts (upper and lower parts in FIG. 6) based on the sense amplifiers S/A1 to S/An. The global bit lines of the bank BANK1 may also be divided into a first group of global bit lines and a second group of global bit lines. The first global bit line group may be shared by the first to x^{th} sectors SEC1 to SECx. The second global bit line group may be shared by the (x+1)^{th} to m^{th} sectors SECx+1 to SECm. Herein, the global bit lines included in the first global bit line group will be referred to as GBL11 to GBL1i, and the global bit lines included in the second global bit line group will be referred to as GBL21 to GBL2i.

Each of the sense amplifiers S/A1 to S/An may be shared by a plurality of corresponding global bit lines from among the global bit lines GBL11 to GBL1i of the first global bit line group, and may further be shared by a plurality of corresponding global bit lines from among the global bit lines GBL21 to GBL2i of the second global bit line group.

The PRAM device 600 may further include the sense amplifier controlling unit S/A CTRL. The sense amplifier controlling unit S/A CTRL may control each of the sense amplifiers S/A1 to S/An to perform a sensing operation for corresponding bit lines by responding to the control signal XCSA. For example, when the first bank signal XBAN1 is enabled and the control signal XCSA instructs operation of the first sense amplifier S/A1, the sense amplifier controlling unit S/A CTRL may activate the first sense amplifier S/A1. The control signal XCSA may include a data of a target to be sensed between the first and second global bit line groups, i.e., it may control selection of the respective bit line groups.

A sensing operation of the PRAM device 600 of FIG. 6 will now be described above with reference to FIGS. 4 and 5.

Referring to FIG. 6, each of the global bit lines GBL11 to GBL1i and GBL21 to GBL2i may include a corresponding global bit line selection transistor GN11 to GN1i and GN21 to GN2i. One end of the transistors GN11 to GN1i and GN21 to GN2i may be connected to a respective global bit line. The other end of the transistors GN11 to GN1i and GN21 to GN2i may be commonly connected to a sense amplifier, e.g., transistors GN11 . . . GN1i may be commonly connected to sense amplifier S/A1. Gates of the transistors may be controlled by global bit line selection signals GY11 to GY1i and GY21 to GY2i.

Each of the global bit line groups may have their own global bit line selection transistors. For example, as shown in FIG. 6, the selection transistors GN11 to GN1i of the first global bit line group may be disposed at the bottom of the x^{th} sector SECx, and the selection transistors GN21 to GN2i of the second global bit line group may be disposed at the top of the (x+1)^{th} sector SECx+1.

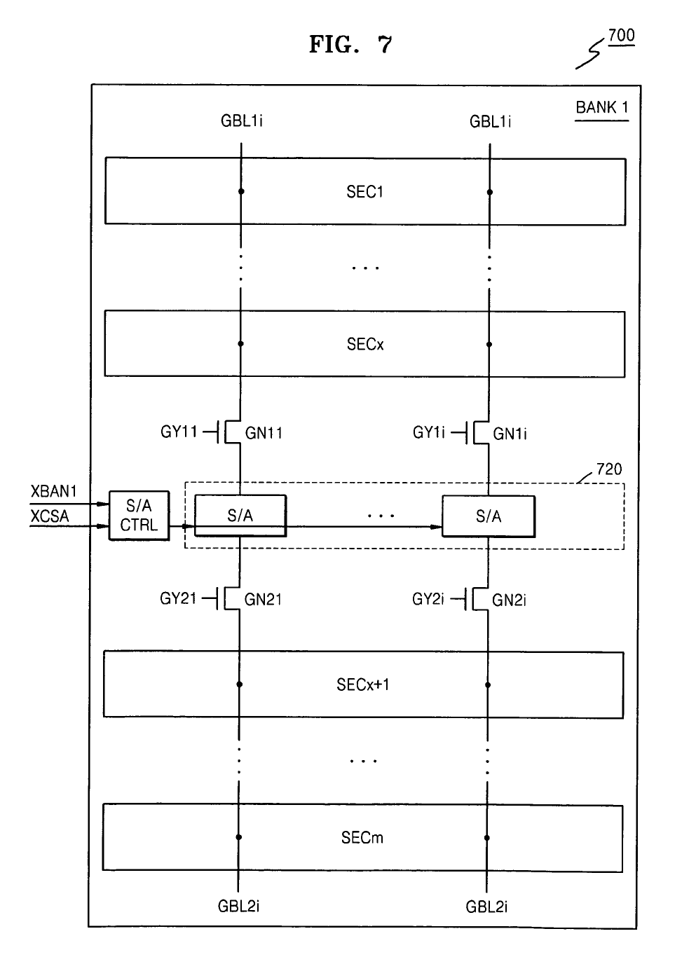

FIG. 7 illustrates a circuit diagram of a PRAM device 700 according to a third embodiment.

The PRAM device 700 of FIG. 7 may be the same as the PRAM device 600 of FIG. 6, except that a single sense amplifier, e.g., S/A1, of a plurality of sense amplifiers 720 may be shared by a single global bit line GBL11 from among the global bit lines of the first global bit line group, as well as a single global bit line GBL21 from among the global bit lines of the second global bit line group. That is, rather than being commonly connected to a sense amplifier, each of the global bit lines in a bit line group may be connected to a respective sense amplifier. Other details of the PRAM device 700 may be similar to those described above in connection with the PRAM device 600, and will not be repeated.

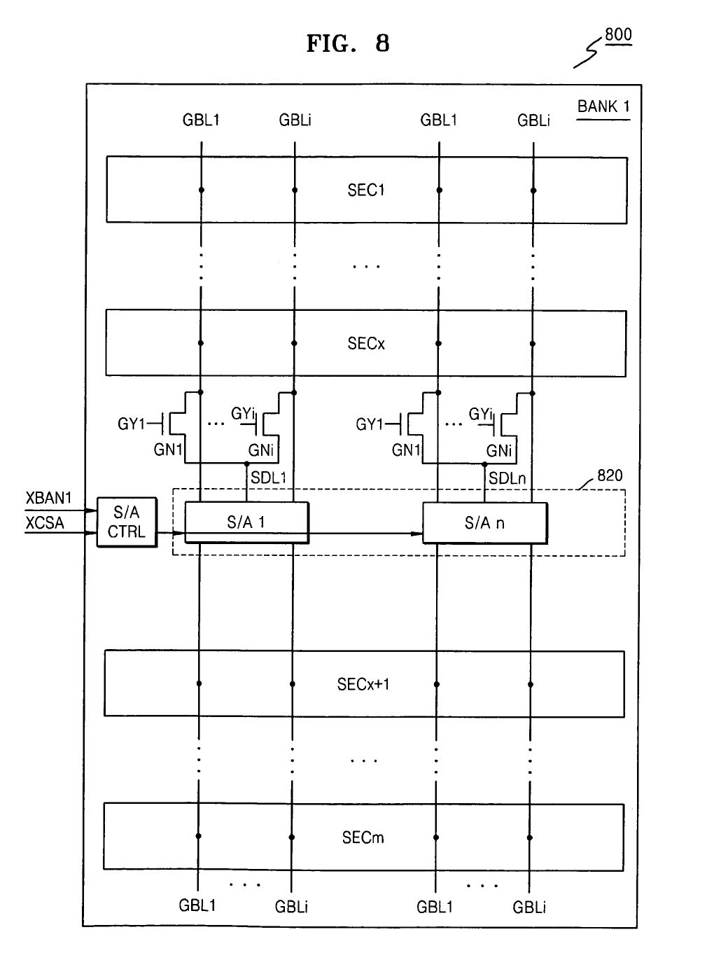

FIG. 8 illustrates a circuit diagram of a PRAM device 800 according to a fourth embodiment.

Referring to FIG. 8, the PRAM device 800, like the PRAM device 600, may include a plurality of sense amplifiers 820 (S/A1 to S/An) in a bank BANK1. However, according to this embodiment, each of the global bit lines GBL1 to GBLi may be shared by all of the sectors SEC1 to SECm, whereas the embodiment described in connection with FIG. 6 had the global bit lines divided into the first group GBL11 to GBL In (for the first to x^{th} sectors SEC1 to SECx) and the second group GBL21 to GBL2n (for the (x+1)^{th} to m^{th} sectors SECx+1 to SECm).

The selection transistors GN1 to GNi that select the global bit lines may be disposed at the bottom of the x^{th} sector SECx (as shown in FIG. 8), or at the top of the (x+1)^{th} sector. Further, although all of the selection transistors GN1 to GNi in FIG. 8 are disposed at the bottom of the x^{th} sector SECx, the location of the selection transistors GN1 to GNi is not limited thereto. For example, the selection transistors connected to the first sense amplifier S/A1 may be disposed at the bottom of the x^{th} sector, as shown in FIG. 8, while the selection transistors connected to the nth sense amplifier may be disposed at the top of the (x+1)^{th} sector (not shown). Operations of the PRAM device 800 of FIG. 8 may be the same as those described above in connection with FIG. 6.

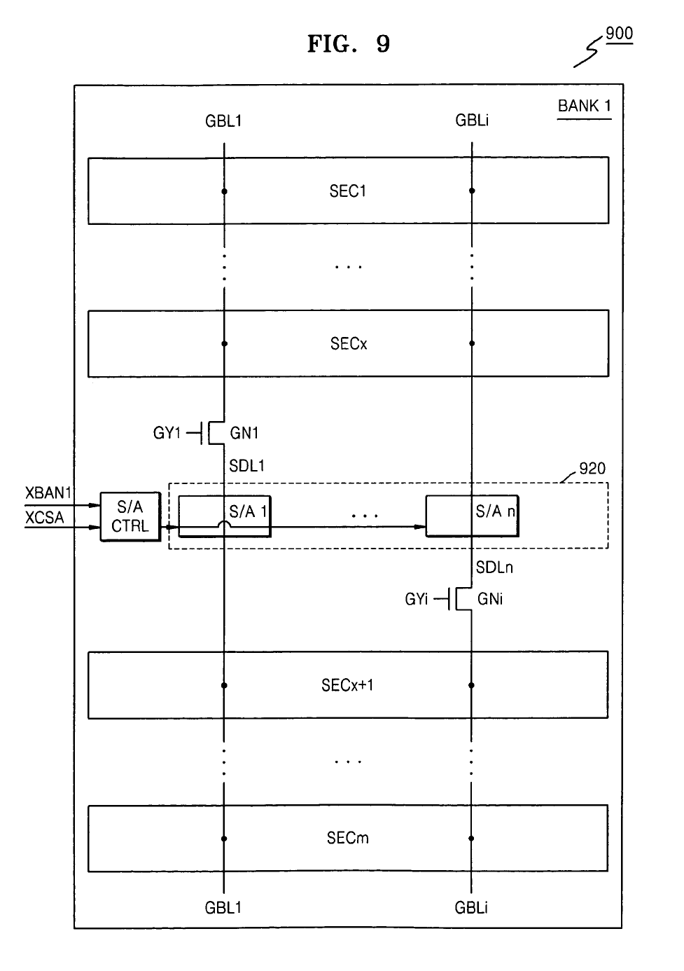

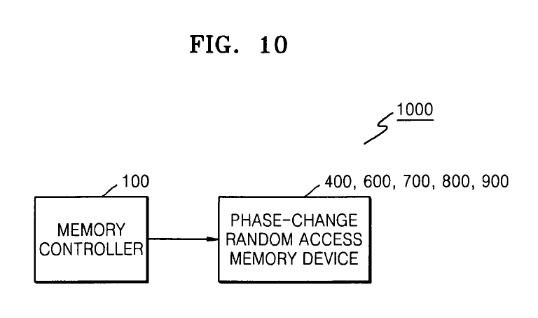

FIG. 9 illustrates a circuit diagram of a PRAM device 900 according to a fifth embodiment.

The PRAM device 900 of FIG. 9 may be generally the same as the PRAM device 800, except that a single sense amplifier, e.g., S/A1, of a plurality of sense amplifiers 920 may be connected to a single global bit line GBL1.

FIG. 10 illustrates a schematic block diagram of a memory system 1000 according to embodiments.

Referring to FIG. 10, the memory system 1000 may include one or more PRAM devices according to embodiments, e.g., PRAM devices 400, 600, 700, 800 and 900, as well as a memory controller 100 that controls the PRAM device(s).

A PRAM device according to embodiments may provide speed, and accuracy of a sensing operation of a sense amplifier may be improved, by disposing a sense amplifier within a bank, and thus reducing parasitic resistance of bit lines. Further, layout area may be reduced.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A phase-change random access memory (PRAM) device, comprising:
a PRAM cell array having a first bank that includes first to m^{th} sectors, where m is a positive integer of at least 2; and
sense amplifiers disposed between an x^{th} sector and an (x+1)^{th} sector of the bank, where x is a positive integer less than m.

2. The PRAM device as claimed in claim 1, further comprising:
a first group of global bit lines connected to the first through x^{th} sectors; and
a second group of global bit lines connected to the (x+1)^{th} through m^{th} sectors.

3. The PRAM device as claimed in claim 2, wherein a plurality of global bit lines from the first group of global bit lines and a plurality of global bit lines from the second group of global bit lines are each connected to a same sense amplifier disposed between the x^{th} sector and the (x+1)^{th} sector.

4. The PRAM device as claimed in claim 2, wherein exactly one global bit line from the first group of global bit lines and exactly one global bit line from the second group of global bit lines are connected to a same sense amplifier disposed between the x^{th} sector and the (x+1)^{th} sector.

5. The PRAM device as claimed in claim 2, further comprising global bit line selection units configured to connect the sense amplifiers to corresponding global bit lines.

6. The PRAM device as claimed in claim 5, wherein the global bit line selection units each include a transistor,
a gate of the transistor is controlled by a global bit line selection signal, and
the transistor is configured to couple a sense amplifier to a corresponding global bit line.

7. The PRAM device as claimed in claim 5, wherein the global bit line selection units are disposed between adjacent sectors.

8. The PRAM device as claimed in claim 5 wherein:
global bit line selection units coupled to the first through x^{th} sectors are disposed between the x^{th} sector and the (x+1)^{th} sector, and
global bit lines selection units coupled to the (x+1)^{th} through m^{th} sectors are disposed between the x^{th} sector and the (x+1)^{th} sector.

9. The PRAM device as claimed in claim 1, further comprising a plurality of global bit lines, each of the global bit lines connected to each of the first to the m^{th} sectors.

10. The PRAM device as claimed in claim 9, wherein each of the sense amplifiers is connected to at least two bit lines of the plurality of global bit lines.

11. The PRAM device as claimed in claim 10, further comprising global bit line selection units configured to couple one of the at least two bit lines to a single sense amplifier.

12. The PRAM device as claimed in claim 11, wherein each of the at least two bit lines is connected to a respective bit line selection unit disposed between the bit line and the sense amplifier.

13. The PRAM device as claimed in claim 9, wherein each of the sense amplifiers is connected to exactly one global bit line of the plurality of global bit lines.

14. The PRAM device as claimed in claim 1, wherein:
the x^{th} sector is an m/2^{th} sector when m is a multiple of 2, and
the x^{th} sector is a (m±1)/2^{th} sector when m is not a multiple of 2.

15. A phase-change random access memory (PRAM) device, comprising:
a PRAM cell array having a plurality of banks; and
a plurality of sense amplifiers, each sense amplifier being connected to at least two banks of the plurality of banks.

16. The PRAM device as claimed in claim 15, wherein:
a first group of global bit lines is connected to a first bank of the plurality of banks, and
a second group of global bit lines is connected to a second bank of the plurality of banks.

17. The PRAM device as claimed in claim 16, wherein a plurality of global bit lines from the first group of global bit lines and a plurality of global bit lines from the second group of global bit lines are each connected to a same sense amplifier.

18. The PRAM device as claimed in claim 15, wherein exactly one global bit line from the first group of global bit lines and exactly one global bit line from the second group of global bit lines are connected to a same sense amplifier.

19. A phase-change random access memory (PRAM) system, comprising:
a PRAM cell array having a first bank that includes first to m^{th} sectors, where m is a positive integer of at least 2; and
a memory controller configured to control operations of the memory cell array, wherein:
sense amplifiers are disposed between an x^{th} sector and an (x+1)^{th} sector of the bank, where x is a positive integer less than m.

20. A method of operating a memory system having a phase-change random access memory (PRAM) cell array, the method comprising:
controlling set and reset states of cells in a bank of the PRAM cell array, the bank having first and second sectors; and
sensing the set and reset states of the cells using sense amplifiers disposed between an x^{th} sector and an (x+1)^{th} sector of the bank, where x is a positive integer less than m.
